(19) United States
(12) Patent Application Publication
(10) Pub. No.: US 2021/0223835 A1
(43) Pub. Date: Jul. 22, 2021

(54) DISPLAY PANEL AND DISPLAY DEVICE

(71) Applicant: WUHAN CHINA STAR OPTOELECTRONICS TECHNOLOGY CO., LTD., Wuhan (CN)

(72) Inventor: Chunlei DU, Wuhan, Hubei (CN)

(21) Appl. No.: 16/300,570

(22) PCT Filed: Sep. 12, 2018
(86) PCT No.: PCT/CN2018/105200

§ 371 Date: Nov. 11, 2018

(30) Foreign Application Priority Data
Jul. 26, 2018 (CN) 201810833308.2

(51) Int. Cl. G06F 1/18; G09G 3/20

(52) U.S. Cl. CPC G06F 1/189; G09G 2300/0426; G09G 3/20

(57) ABSTRACT

The present disclosure provides a display panel and a display device. The display panel includes a display region and a non-display region. The non-display region includes a first driving chip bonding region. The first driving chip bonding region includes a substrate and at least two rows of first pins formed on the substrate along a first direction, each row of the first pins includes at least two of the first pins formed along a second direction. Thicknesses of the first pins formed near the display region are greater than thicknesses of the first pins formed far from the display region.

### BACKGROUND OF THE INVENTION

### Field of Invention

The present application relates to displays, and particularly to a display panel and a display device.

### Description of Prior Art

In flat panel display technology, organic light emitting diode (OLED) displays have many advantages such as thin, active light, fast response time, wide viewing angles, wide color range, high brightness, and low power consumption, and will be third generation display technology after liquid crystal display (LCD) device.

Functions of displaying, touch controlling place detection, fingerprint identification, or touch controlling pressure detection are implemented in a connecting area outside of the driving chips. Because differences of pressures, parts of connecting pins of controlling module are badly contacted to pins of the display panel to result in signal crosstalks and uneven displaying.

### SUMMARY OF THE INVENTION

The application mainly provides a display panel and a display device to solve technical problems of signal crosstalks and uneven displaying of the display panel.

For the above-mentioned objective, the present disclosure employs the following technical schemes.

The present disclosure provides a display panel including a display region and a non-display region, the non-display region includes a first driving chip bonding region, the first driving chip bonding region includes:

a substrate;

at least two rows of first pins formed on the substrate along a first direction, each row of the first pins comprises at least two of the first pins formed along a second direction;

thicknesses of the first pins formed near the display region are greater than thicknesses of the first pins formed far from the display region; and

the thicknesses of the first pins are gradually decreased along a direction from the display region to the non-display region, and the thicknesses of the first pins are same along the same row.

In the display panel of the present disclosure, each of the first pin comprises a first metal layer formed on the substrate and a second metal layer formed on the first metal layer; and

the first metal layer and a gate electrode layer of the display region are formed in a same layer, and the second metal layer and a source and drain electrode layer of the display region are formed in a same layer.

In the display panel of the present disclosure, a thickness of the second metal layer formed near the display region is greater than a thickness of the second metal layer formed far from the display region.

In the display panel of the present disclosure, each of the first pins formed near the display region further comprises a third metal layer.

In the display panel of the present disclosure, the display panel further comprise a second driving chip bonding region, the first driving chip bonding region is defined near the display region, the second driving chip bonding region is defined far from the display region; and

the second driving chip bonding region comprises at least two of the second pins formed along the first direction.

In the display panel of the present disclosure, thicknesses of the second pins formed near the second driving chip bonding region are same as thicknesses of the first pins formed near the second driving chip bonding region.

In the display panel of the present disclosure, a film layer structure of the second pins is same as a film layer structure of the first pins formed near the second driving chip bonding region.

In the display panel of the present disclosure, the first pins are signal output ends, and the second pins are signal input ends.

A display panel includes a display region and a non-display region, the non-display region includes a first driving chip bonding region, the first driving chip bonding region includes:

a substrate;

at least two rows of first pins formed on the substrate along a first direction, each row of the first pins comprises at least two of the first pins formed along a second direction; and

thicknesses of the first pins formed near the display region are greater than thicknesses of the first pins formed far from the display region.

In the display panel of the present disclosure, each of the first pin comprises a first metal layer formed on the substrate and a second metal layer formed on the first metal layer; and

the first metal layer and a gate electrode layer of the display region are formed in a same layer, and the second metal layer and a source and drain electrode layer of the display region are formed in a same layer.

In the display panel of the present disclosure, a thickness of the second metal layer formed near the display region is greater than a thickness of the second metal layer formed far from the display region.

In the display panel of the present disclosure, each of the first pins formed near the display region further comprises a third metal layer.

In the display panel of the present disclosure, the display panel further comprise a second driving chip bonding region, the first driving chip bonding region is defined near the display region, the second driving chip bonding region is defined far from the display region; and

the second driving chip bonding region comprises at least two of the second pins formed along the first direction.

In the display panel of the present disclosure, thicknesses of the second pins formed near the second driving chip bonding region are same as thicknesses of the first pins formed near the second driving chip bonding region.

In the display panel of the present disclosure, a film layer structure of the second pins is same as a film layer structure of the first pins formed near the second driving chip bonding region.

In the display panel of the present disclosure, the first pins are signal output ends, and the second pins are signal input ends.

The present disclosure also provides a display device, the display device comprises the display panel.

The beneficial effect of this invention is: a plurality of first pins with different thicknesses are formed on a driving chip controlling region to improve a bonding performance between a display panel and a controlling module, to solve the issues of signal crosstalks and uneven displaying of the display panel.

### BRIEF DESCRIPTION OF THE DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a top view of a display panel of one exemplary embodiment according to the present disclosure.

FIG. 2 is a cross sectional view of the display panel FIG. 1 taken along A-A.

FIG. 3 is a cross sectional view of the display panel FIG. 1 taken along B-B.

FIG. 4 is a film layer structure of a first exemplary embodiment of the display panel FIG. 1 taken along C-C.

FIG. 5 is a film layer structure of a second exemplary embodiment of the display panel FIG. 1 taken along C-C.

FIG. 6 is a film layer structure of a third exemplary embodiment of the display panel FIG. 1 taken along C-C.

### DETAILED DESCRIPTION OF THE PREFERRED EMBODIMENTS

The description of following embodiment, with reference to the accompanying drawings, is used to exemplify specific embodiments which may be carried out in the present disclosure. Directional terms mentioned in the present disclosure, such as “top”, “bottom”, “front”, “back”, “left” “right”, “inside”, “outside”, “side”, etc, are only used with reference to the orientation of the accompanying drawings. Therefore, the used directional terms are intended to illustrate, but not to limit, the present disclosure. In the drawings, the components having similar structures are denoted by same numerals.

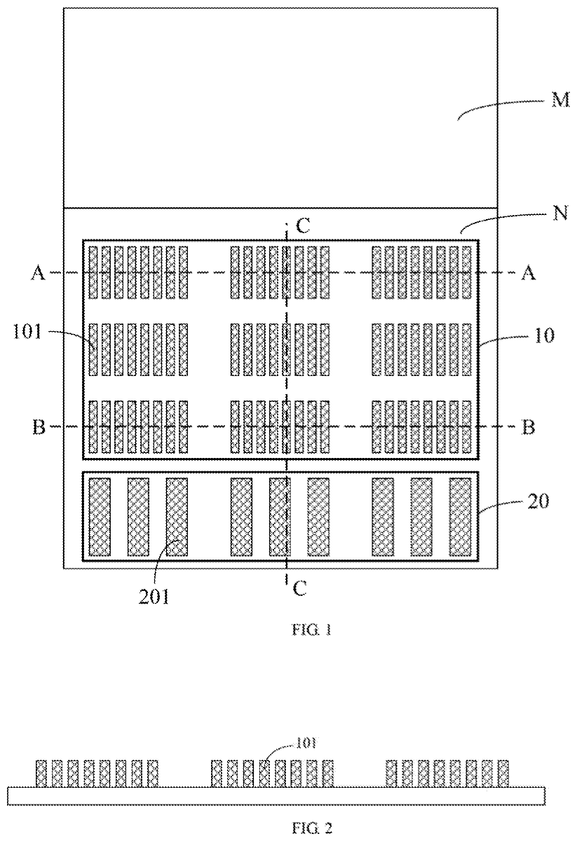

Referring to FIG. 1. FIG. 1 is a top view of a display panel of one exemplary embodiment according to the present disclosure. The dis display panel includes a display region M and a non-display region N. The non-display region includes a first driving chip bonding region 10. The first driving chip bonding region 10 includes a substrate and a plurality of first pins 101 formed on the substrate.

In one embodiment, the first driving chip bonding region 10 includes at least two rows of the first pins 101 formed along a first direction, and each row of the first pins 101 includes at least two of the first pins 101 formed along a second direction. Thicknesses of the first pins 101 formed near the display region M are greater than thicknesses of the first pins 101 formed far from the display region M. In one embodiment, the first direction can be defined as a vertical direction, and the second direction can be defined as a horizontal direction.

The first driving chip bonding region 10 includes three rows of the first pins 101 formed along the first direction, and each raw of the first pins 101 includes a plurality of the first pins 101 formed along the second direction. Numbers of the first pins 101 are same in each row.

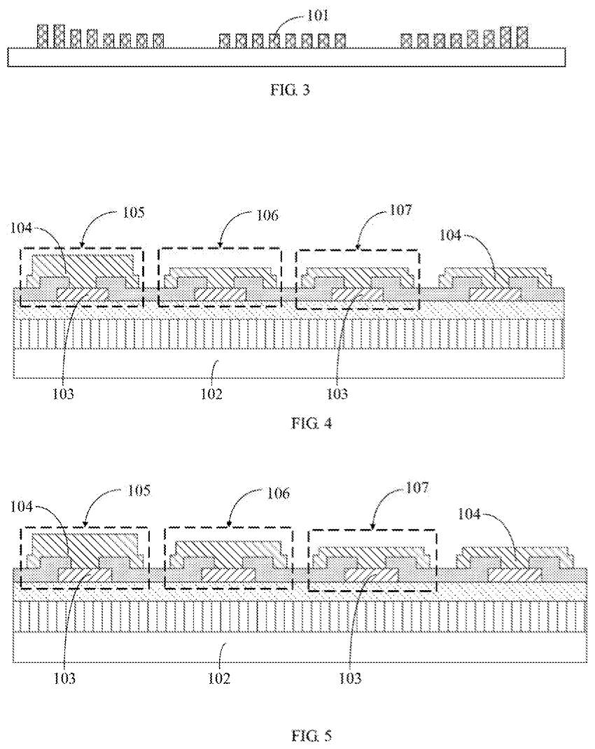

Referring to FIG. 2, FIG. 2 is a cross sectional view of the display panel FIG. 1 taken along A-A. The thicknesses of the first pins 101 are same along the same row. Referring to FIG. 3, FIG. 3 is a cross sectional view of the display panel FIG. 1 taken along B-B. The thicknesses of the first pins 101 are different along the same row. In the second direction, the thicknesses of the first pins 101 are increased first and then decreased.

The thicknesses of each row of the first pins 101 include the exemplary embodiments shown in FIG. 2 and FIG. 3 rather than limiting of the present disclosure.

The display panel also includes a second driving chip bonding region 20. The first driving chip bonding region 10 is defined near the display region M. The second driving chip bonding region 20 is defined far from the display region M. The second driving chip bonding region 20 includes at least two second pins 201 formed along the first direction.

In one embodiment, the thicknesses of the second pins 201 are same along the same row.

In one embodiment, the first pins 101 can be signal output ends. The second pins 102 can be signal input ends.

Referring to FIG. 1, the second driving chip bonding region 20 is defined far from the display region M. The second driving chip bonding region 20 includes one row of the first pins 201. Each row of the second pins 21 includes a plurality of the second pins 201. A projection area of the second pin 201 projected on the substrate is greater than a projection area of the first pin 101 projected on the substrate shown in the top view.

Referring to FIG. 4, FIG. 4 is a film layer structure of a first exemplary embodiment of the display panel FIG. 1 taken along C-C. The first driving chip bonding region 10 includes a substrate 102, a first metal layer 103 and a second metal layer 104.

In one embodiment, because the display panel is made by the COP process, the substrate 102 can be made of a flexible substrate.

In one embodiment, the flexible substrate can be made of a polyimide film. The polyimide film is the best film insulation material in the world, has a strong tensile strength, and is generated by a polycondensation acted between phthalic anhydride and diamine diphenyl ether in a strong polar solvent to cast a film and then acted in an imidization.

The first metal layer 103 is formed on the substrate 102. The first metal layer 102 and a gate electrode layer of the display region M are formed in a same layer. Metal materials of the first metal layer 103 can be made of a metal of molybdenum, aluminum, aluminum nickel, molybdenum tungsten, chromium, or copper, and can be made of a combination of the above metal materials. In one embodiment, material of the first metal layer 103 can be made of molybdenum.

The second metal layer 104 can be formed on the first metal layer 103. The second metal layer 104 and a source and drain electrode layer of the display region M are formed in a same layer. Metal materials of the second metal layer 104 can be made of a metal of molybdenum, aluminum, aluminum nickel, molybdenum tungsten, chromium, copper, or titanium-aluminium alloy, and can be made of a combination of the above metal materials. In one embodiment, material of the second metal layer 104 is made of titanium-aluminium alloy.

In one embodiment, a thickness of the second metal layer 104 formed near the display region M is greater than a thickness of the second metal layer 104 formed far from the display region M. The first driving chip bonding region 10 can include a first area 105, a second area 106, and a third area 107.

A thickness of the second metal layer 104 defined in the first area 105 is greater than a thickness of the second metal layer 104 defined in the second area 106 and the third area 107. A thickness of the second metal layer 104 defined in the second area 106 is equal to a thickness of the second metal layer 104 defined in the third area 107. In one embodiment, the second metal layer 104 with different thicknesses is formed to make the first pins 101 with different thicknesses.

A film layer structure of the second pins 201 is same as a film layer structure of the first pins 101 formed near the second driving chip bonding region 20. Referring to FIG. 4, an area adjacent to the third area 107 is the film layer structure of the second pins 201. The film layer substrate of the second pins 201 is same as the layer substrate of the third area 104 defined near the second driving chip bonding region 20 shown in FIG. 4.

The thicknesses of the second pins 201 are same as the thicknesses of the first pins 101 formed near the second driving chip bonding region 20. The thicknesses of the second pins 201 are same as the thicknesses of the third area 107 formed near the second driving chip bonding region 20 shown in FIG. 4.

Referring to FIG. 5, FIG. 5 is a film layer structure of a second exemplary embodiment of the display panel FIG. 1 taken along C-C. Along a direction from the display region M to the non-display region N, the thicknesses of the first pins 101 are gradually decreased. The thickness of the second metal layer 104 defined in the first area 105 is greater than the thickness of the second metal layer 104 defined in the second area 106. The thickness of the second metal layer 104 defined in the second area 106 is greater than the thickness of the second metal layer 104 defined in the third area 107. The thickness and the film layer structure of the second pins 201 are same as the thickness and the film layer structure of the third area 107.

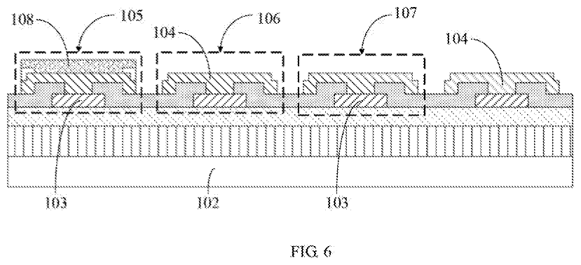

Referring to FIG. 6, FIG. 6 is a film layer structure of a third exemplary embodiment of the display panel FIG. 1 taken along C-C. The first pins 101 formed near the display region M also include a third metal layer 108. In one embodiment, the display region M also includes the third metal layer 108. The thicknesses of the second metal layer 104 defined in the first area 105, the second area 106, and the third area 107 are equal to each other. The third metal layer 108 is formed to make the first pins 101 with different thickness formed in the first driving chip bonding area 10.

In one embodiment, metal material of the third metal layer 108 can be same as metal material of the second metal layer 104.

In one embodiment, a flexible layer, a buffer layer, and a gate insulating layer can be formed in a layer of the display region M and formed between the substrate 102 and the first metal layer 103. An insulating interlayer is formed in the layer of the display region M and formed between the first metal layer 103 and the second metal layer 104. A passivation layer can be formed in the layer of the display region M and formed between the second metal layer 104 and the third metal layer.

The present disclosure also provides a display device. The display device includes the above display panel. Understandable, the display device includes telephones, tablet computers, computer displays, game machines, televisions, display screens, wearable devices and other domestic appliances or household appliances with display functions rather than limiting of the present disclosure.

The present disclosure provides a display panel and a display device. The display panel includes a display region and a non-display region. The non-display region includes a first driving chip bonding region. The first driving chip bonding region includes a substrate and at least two rows of first pins formed on the substrate along a first direction, each row of the first pins includes at least two of the first pins formed along a second direction. Thicknesses of the first pins formed near the display region are greater than thicknesses of the first pins formed far from the display region. The first pins with different thicknesses are formed on a driving chip controlling region to improve a bonding performance between a display panel and a controlling module, to solve the issues of signal crosstalks and uneven displaying of the display panel.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. A display panel, comprising a display region and a non-display region, wherein the non-display region comprises a first driving chip bonding region, the first driving chip bonding region comprises:
a substrate;
at least two rows of first pins formed on the substrate along a first direction, wherein each row of the first pins comprises at least two of the first pins formed along a second direction;
wherein thicknesses of the first pins formed near the display region are greater than thicknesses of the first pins formed far from the display region; and
the thicknesses of the first pins are gradually decreased along a direction from the display region to the non-display region, and the thicknesses of the first pins are same along the same row.

2. The display panel of claim 1, wherein each of the first pin comprises a first metal layer formed on the substrate and a second metal layer formed on the first metal layer;
wherein the first metal layer and a gate electrode layer of the display region are formed in a same layer, and the second metal layer and a source and drain electrode layer of the display region are formed in a same layer.

3. The display panel of claim 2, wherein a thickness of the second metal layer formed near the display region is greater than a thickness of the second metal layer formed far from the display region.

4. The display panel of claim 2, wherein each of the first pins formed near the display region further comprises a third metal layer.

5. The display panel of claim 1, wherein the display panel further comprise a second driving chip bonding region, the first driving chip bonding region is defined near the display region, the second driving chip bonding region is defined far from the display region;
wherein the second driving chip bonding region comprises at least two of the second pins formed along the first direction.

6. The display panel of claim 1, wherein thicknesses of the second pins formed near the second driving chip bonding region are same as thicknesses of the first pins formed near the second driving chip bonding region.

7. The display panel of claim 1, wherein a film layer structure of the second pins is same as a film layer structure of the first pins formed near the second driving chip bonding region.

8. The display panel of claim 1, wherein the first pins are signal output ends, and the second pins are signal input ends.

9. A display panel, comprising a display region and a non-display region, wherein the non-display region comprises a first driving chip bonding region, the first driving chip bonding region comprises:
a substrate;
at least two rows of first pins formed on the substrate along a first direction, wherein each row of the first pins comprises at least two of the first pins formed along a second direction;
wherein thicknesses of the first pins formed near the display region are greater than thicknesses of the first pins formed far from the display region.

10. The display panel of claim 9, wherein each of the first pin comprises a first metal layer formed on the substrate and a second metal layer formed on the first metal layer;
wherein the first metal layer and a gate electrode layer of the display region are formed in a same layer, and the second metal layer and a source and drain electrode layer of the display region are formed in a same layer.

11. The display panel of claim 10, wherein a thickness of the second metal layer formed near the display region is greater than a thickness of the second metal layer formed far from the display region.

12. The display panel of claim 10, wherein each of the first pins formed near the display region further comprises a third metal layer.

13. The display panel of claim 9, wherein the display panel further comprise a second driving chip bonding region, the first driving chip bonding region is defined near the display region, the second driving chip bonding region is defined far from the display region;
wherein the second driving chip bonding region comprises at least two of the second pins formed along the first direction.

14. The display panel of claim 9, wherein thicknesses of the second pins formed near the second driving chip bonding region are same as thicknesses of the first pins formed near the second driving chip bonding region.

15. The display panel of claim 9, wherein a film layer structure of the second pins is same as a film layer structure of the first pins formed near the second driving chip bonding region.

16. The display panel of claim 9, wherein the first pins are signal output ends, and the second pins are signal input ends.

17. A display device, wherein the display device comprises the display panel of claim 1.
